(19) United States
(12) Patent Application Publication
(10) Pub. No.: US 2026/0269194 A1
(43) Pub. Date: Sep. 10, 2026

(54) Charged Particle Beam Device

(71) Applicant: Hitachi High-Tech Corporation, Minato-ku, Tokyo (JP)

(72) Inventors: Hiroshi OBA, Tokyo (JP); Yasutaka OTSUKA, Tokyo (JP); Koji NAGAHARA, Tokyo (JP); Yasuhiko SUGIYAMA, Tokyo (JP)

(21) Appl. No.: 19/166,983

(22) PCT Filed: Apr. 26, 2023
(86) PCT No.: PCT/JP2023/016391

§ 371 Date: Sep. 19, 2025

(51) Int. Cl. H01J 37/32

(52) U.S. Cl. CPC H01J 37/32651; H01J 37/321; H01J 2237/0262

(57) ABSTRACT

A charged particle beam device 10 capable of preventing etching in a plasma generation chamber 18, preventing heat generation of an electrostatic shield 4 formed inside the plasma generation chamber 18, and obtaining a stable charged particle beam is implemented. The charged particle beam device 10 includes: a cylindrical dielectric body 14 forming the plasma generation chamber 18 therein; a cylindrical outer shield 3 disposed to surround an outer surface of the cylindrical dielectric body 14; the inner shield 4 disposed inside the plasma generation chamber 18 and facing the outer shield 3 via the dielectric body 14; a coil 2 disposed on an outer periphery of the outer shield 3 and configured to generate a radio frequency to generate plasma in the plasma generation chamber 18; an envelope 9 surrounding the coil 2, the outer shield 3, and the dielectric body 14; an aperture electrode 7 in which a hole 6 for extracting ions from the plasma generation chamber 18 is formed; and an extraction electrode 8 to which a voltage for extracting ions from the plasma generation chamber 18 is applied. A plurality of slits are formed in each of the outer shield 3 and the inner shield 4.

### TECHNICAL FIELD

The present invention relates to a charged particle beam device.

### BACKGROUND ART

As a method of analyzing an internal structure of a sample such as a semiconductor device or performing three-dimensional observation, a focused ion beam (FIB) device is known.

PTL 1 discloses a configuration for reducing capacitive coupling with plasma in a charged particle beam and system in order to obtain a small energy width desirable for a purpose of forming a charged particle beam. A conductive shield for reducing the capacitive coupling with the plasma is formed in a plasma chamber.

### CITATION LIST

### Patent Literature

PTL 1: JP2013-89584A

### SUMMARY OF INVENTION

### Technical Problem

In an inductively coupled plasma ion source mounted on a charged particle beam device, an aperture electrode for limiting an ion extraction region is provided between an extraction electrode and plasma. In order to reduce an ion generation region, an aperture of the aperture electrode is as small as several tens of um to several hundreds of um, and a beam current greatly changes according to damage of the aperture electrode.

The damage to the aperture electrode includes enlargement and reduction of the aperture of the aperture electrode. The aperture may be enlarged by etching a aperture by plasma. Therefore, it is necessary to select a plasma generation condition for lowering the plasma potential and a material of a component of the plasma generation chamber having a high sputtering energy threshold.

On the other hand, the aperture is reduced when a component of the plasma generation chamber is sputtered by the plasma and composition thereof is precipitated on an inner wall of the aperture of the aperture electrode.

It is considered that, by a countermeasure against the enlargement of the aperture, the sputtering of the component is prevented and the composition thereof is not precipitated. However, in the inductively coupled plasma ion source for the charged particle beam device, a dielectric body which is a member constituting the plasma generation chamber is precipitated. Therefore, there is a problem that an ion beam current changes with time.

In the charged particle beam device, a potential serving as energy of an ion beam is locally applied to plasma. In order to miniaturize the inductively coupled plasma ion source, a coil, a faraday shield, an envelope, and the like are set to a ground potential. In order to transmit an electromagnetic wave generated by the coil to the plasma, the plasma generation chamber is made of a dielectric body (ceramic). A potential difference is generated between the faraday shield or the coil and the plasma, and an electric field affects an inside of the plasma generation chamber.

Ions in the plasma are accelerated toward an inner wall of the plasma generation chamber and collide with the inner wall with high energy to sputter the dielectric body. Here, since stable molecules such as Xe, Ar, N2, and O2 are used as a plasma raw material gas, a chemical reaction may not be considered.

As a countermeasure for sputtering, it is conceivable to (1) boost the potential of the coil or the faraday shield to an acceleration potential, or to (2) use the faraday shield for the inner wall of the plasma generation chamber.

The countermeasure (1) is inappropriate since this countermeasure may require the inductively coupled plasma ion source to be large in size. As the countermeasure (2), a material having a high electrical conductivity is preferably used since an eddy current is generated in the faraday shield by capacitive coupling or inductive coupling with the coil to cause a loss of radio frequency power. However, since the material has a low sputtering energy threshold, the sputtering by the plasma occurs when the material is provided inside the plasma generation chamber, and the problem cannot be solved. On the other hand, a material having a low sputtering energy threshold has a small electrical conductivity, and thus may cause a problem of heating and cooling, or a new problem such as outgas due to temperature rise.

An object of the invention is to implement a charged particle beam device capable of preventing etching in a plasma generation chamber, preventing heat generation of an electrostatic shield in the plasma generation chamber, and obtaining a stable charged particle beam.

### Solution to Problem

In order to achieve the above object, the invention is configured as follows.

A charged particle beam device 10 includes: a tubular dielectric body 14 formed with a plasma generation chamber 18 therein; a cylindrical outer shield 3 disposed to surround an outer surface of the dielectric body 14; an inner shield 4 disposed inside the plasma generation chamber 18 and facing the outer shield 3 through the dielectric body 14; a coil 2 disposed on an outer periphery of the outer shield 3 and configured to generate a radio frequency to generate plasma in the plasma generation chamber 18; an envelope 9 surrounding the coil 2, the outer shield 3, and the dielectric body 14; an aperture electrode 7 formed with a hole 6 for extracting ions from the plasma generation chamber 18; and an extraction electrode 8 to which a voltage for extracting ions from the plasma generation chamber 18 is applied. A plurality of slits are formed in each of the outer shield 3 and the inner shield 4.

### Advantageous Effects of Invention

According to the invention, it is possible to implement a charged particle beam device capable of preventing etching in a plasma generation chamber, preventing heat generation of an electrostatic shield in the plasma generation chamber, and obtaining a stable charged particle beam.

### BRIEF DESCRIPTION OF DRAWINGS

FIG. 1 is a schematic configuration diagram illustrating an entire composite beam device to which embodiment of the invention is applied.

FIG. 2 is a schematic configuration diagram of an embodiment, and is a schematic cross-sectional view of a main part of an ion beam barrel illustrated in FIG. 1.

FIG. 3 is a schematic side view of an electrostatic shield having a cylindrical shape.

FIG. 4 is a schematic side view of a modification of the electrostatic shield illustrated in FIG. 3.

### DESCRIPTION OF EMBODIMENTS

Hereinafter, an embodiment of the invention will be described with reference to the drawings.

### Embodiments

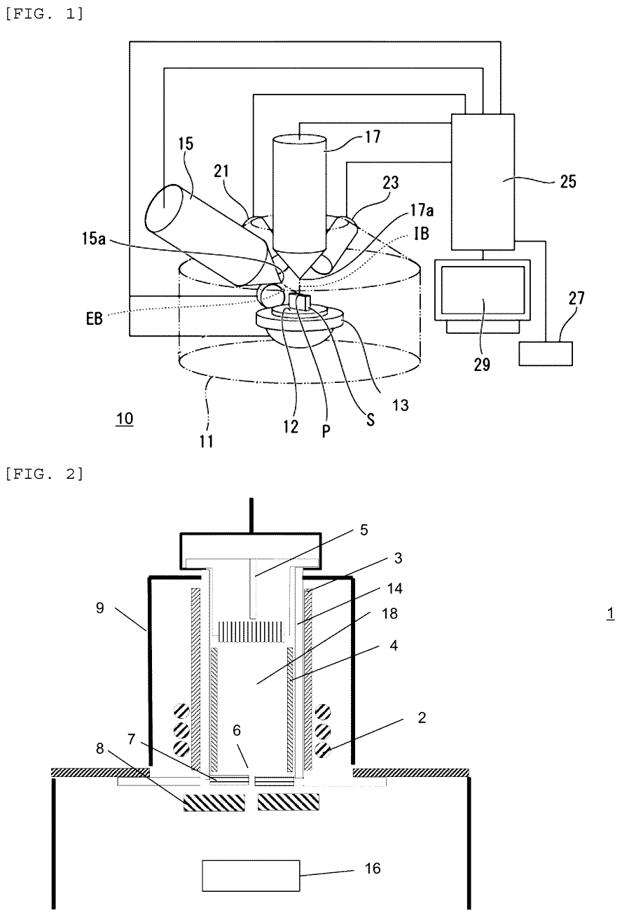

FIG. 1 is a schematic configuration diagram illustrating an entire charged particle beam device 10 to which one embodiment of the invention is applied.

The charged particle beam device 10 according to one embodiment of the invention includes a sample chamber 11 capable of maintaining an inside in a vacuum state, and a sample holder 12 capable of fixing a sample stage 13 for placing a sample S inside the sample chamber 11.

The charged particle beam device 10 includes an ion beam barrel 17 (ion beam device) that irradiates an irradiation target, for example, the sample S, with an ion beam IB within a predetermined irradiation region (that is, a scanning range) inside the sample chamber 11. The ion beam IB having a beam diameter of, for example, 1 μm or less is emitted from an ion beam barrel front end portion 17a of the ion beam barrel 17 as an emission end.

The charged particle beam device 10 includes an electron beam barrel 15 (electron beam device) that irradiates an irradiation target, for example, the sample S, with an electron beam EB from an electron beam barrel front end portion 15a within a predetermined irradiation region inside the sample chamber 11.

The charged particle beam device 10 further includes a secondary charged particle detector 21 that detects secondary electrons generated from the sample S by the irradiation with the electron beam EB. The secondary charged particle detector 21 detects an intensity (that is, an amount of secondary charged particles) of secondary charged particles emitted from the irradiation target, such as the sample S, when the irradiation target is irradiated with an electron beam, and outputs information on a detected amount of the secondary charged particles.

The secondary charged particle detector 21 is disposed inside the sample chamber 11 at a position where the amount of the secondary charged particles can be detected, for example, at a position obliquely above the irradiation target such as the sample S within the irradiation region.

The charged particle beam device 10 includes a gas supply unit 23 that supplies a gas to a surface of the irradiation target, for example, the sample S. The gas supply unit 23 includes, for example, a nozzle having an outer diameter of about 200 μm.

The gas supply unit 23 supplies an etching gas for selectively promoting etching of the sample by the ion beam, a deposition gas for forming a deposition film by a deposit such as a metal or an insulator on the surface of the sample S, and the like.

The charged particle beam device 10 includes a control device 25, a display device 29, and an input device 27. The control device 25 is a control unit for controlling the ion beam barrel 17, the electron beam barrel 15, the secondary charged particle detector 21, the gas supply unit 23, and the like constituting the charged particle beam device 10.

The ion beam IB and the electron beam EB intersect at an intersection point P.

The control device 25 includes, for example, a personal computer and an interface. The display device 29 displays an image of the sample S or the like based on the secondary charged particles detected by the secondary charged particle detector 21. Commands, data, and the like are input to the control device 25 by the input device 27.

FIG. 2 is a schematic cross-sectional view of a main part of the ion beam barrel 17 in the charged particle beam device 10 illustrated in FIG. 1.

In FIG. 2, the coil 2, a faraday shield 3 (outer shield), the dielectric body 14, the electrostatic shield 4 (inner shield), the aperture electrode 7, and a gas insulation introduction path 5 are disposed inside the envelope 9. The envelope 9, the coil 2, the faraday shield 3, the dielectric body 14, the electrostatic shield 4, the aperture electrode 7, and the gas insulation introduction path 5 constitute an ion source 1. The plasma generation chamber 18, the coil 2, and the outer shield 3 disposed on an outer wall are filled with an insulating fluid by the envelope 9.

The coil 2 is disposed on an outer periphery of the faraday shield 3, and the faraday shield 3 is disposed on an outer periphery of the tubular dielectric body 14. The plasma generation chamber 18 is formed by the dielectric body 14. The coil 2 applies a radio frequency to generate plasma in the plasma generation chamber 18.

The electrostatic shield 4 is disposed on an inner wall of the dielectric body 14 that defines the plasma generation chamber 18. The electrostatic shield 4 and the faraday shield 3 face each other through the dielectric body 14.

A raw material gas of the plasma is introduced into the plasma generation chamber 18 from the gas insulation introduction path 5.

The ion extraction hole 6 is formed in the aperture electrode 7, and ions from the ion extraction hole 6 pass through the extraction electrode 8 and an electrostatic lens 16.

The aperture electrode 7 is connected to the aperture electrode 7 in which the ion extraction hole 6 is formed. Accordingly, sputtering can be prevented.

The faraday shield 3 is provided on an outer wall of the plasma generation chamber 18 defined by the dielectric body 14, and capacitive coupling between the coil 2 and the generated plasma is prevented.

On the other hand, the electrostatic shield 4 made of metal is provided to fix a potential of an inner wall of the plasma generation chamber 18. The faraday shield 3 is made of a material having a high electrical conductivity such as Cu (copper), Ag (silver), or Pt (platinum), and has a cylindrical shape with a slit.

As the material of the electrostatic shield 4, a material having a low sputtering energy threshold, for example, any one of W (tungsten), Mo (molybdenum), and Nb (niobium) is selected. A shape of the electrostatic shield 4 is a cylindrical shape, and is provided with a slit similarly to that of the faraday

Although positions of the slits of the faraday shield 3 and the electrostatic shield 4 are matched, the slits have a dimensional relationship in which the internal electrostatic shield 4 cannot be seen from the coil 2 side.

Accordingly, capacitive coupling between the coil 2 and the internal electrostatic shield 4 is eliminated, and a radio frequency loss in the internal electrostatic shield 4 can be reduced.

An acceleration potential is applied to the electrostatic shield 4. For example, the acceleration potential is applied by connection to an electrode including an ion extraction region limiting aperture. An electric field is generated between the coil 2 or the faraday shield 3 and an internal electrode, and an electric field caused by the coil 2 or the faraday shield 3 is not generated between the plasma and the internal electrode or the inner wall of the plasma generation chamber 18.

A potential of the faraday shield 3 is a ground potential, and a potential of the electrostatic shield 4 is a plasma potential. That is, the faraday shield 3 is grounded to have the ground potential, and a voltage is applied to the electrostatic shield 4 to have the plasma potential.

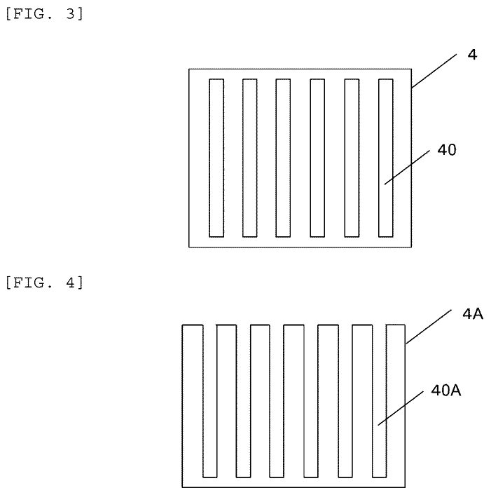

FIG. 3 is a schematic side view of the electrostatic shield 4 having a cylindrical shape. A plurality of slits 40 are formed in an electrostatic shield 34.

The shape of the faraday shield 3 is substantially the same as the shape of the electrostatic shield 4. Therefore, illustration of the shape of the faraday shield 3 is omitted. As described above, the slits are formed such that the slit of the faraday shield 3 and the slit 40 of the electrostatic shield 4 are matched, but the slits have the dimensional relationship in which the internal electrostatic shield 4 cannot be seen from the coil 2 side.

FIG. 4 is a schematic side view of an electrostatic shield 4A which is a modification of the electrostatic shield 4 illustrated in FIG. 3. As illustrated in FIG. 4, the electrostatic 4A has a comb shape in which a plurality of slits 40A are formed. In other words, the electrostatic shield 4A has a comb shape in which a plurality of strips are formed and one ends of the plurality of strips are connected to one another. The slits 40A are each formed between adjacent ones of the plurality of strips.

Even with the comb-shaped electrostatic shield 4A, the same effect as that of the electrostatic shield 4 having the shape illustrated in FIG. 3 can be obtained.

The shape of the faraday shield 3 can also be substantially the same as the shape of the electrostatic shield 4A. However, although positions of the slits 40A of the electrostatic shield 4A and the slits of the faraday shield 3 are matched, the slits have the dimensional relationship in which the internal electrostatic shield 4 cannot be seen from the coil 2 side.

According to one embodiment of the invention, etching of the inner wall of the plasma generation chamber 18 can be prevented, and heat generation of the electrostatic shield 4 formed inside can be prevented.

Further, the heat generation in the electrostatic shield 4 can be prevented by matching phases of slits 30 formed in the faraday shield 3 and the slits formed in the electrostatic shield 4.

In addition, the electrostatic shield 4 is formed inside the plasma generation chamber 18, the faraday shield 3 is formed outside the plasma generation chamber 18, and appropriate materials can be selected for respective components by dividing roles of the shields. For example, Cu, Ag, Pt, or the like can be selected as the material of the faraday shield 3, and W, Mo, or the like can be selected as the material of the electrostatic shield 4.

Since the invention has the configuration as described above, it is possible to implement the charged particle beam device 10 capable of preventing the etching in the plasma generation chamber 18, preventing the heat generation of the electrostatic shield 4 formed inside the plasma generation chamber 18, and obtaining a stable charged particle beam.

### REFERENCE SIGNS LIST

1: ion source
2: coil
3: faraday shield (outer shield)
4, 4A: electrostatic shield (inner shield)
5: gas insulation introduction path
6: ion extraction hole
7: aperture electrode
8: extraction electrode
9: envelope
10: charged particle beam device
11: sample chamber
12: sample holder
13: sample stage
14: dielectric body
15: electron beam barrel
15a: electron beam barrel front end portion
16: electrostatic lens
17: ion beam barrel
17a: ion beam barrel front end portion
18: plasma generation chamber
21: secondary charged particle detector
23: gas supply unit
25: control device
27: input device
29: display device
40, 40A: slit
EB: electron beam
IB: ion beam
P: intersection point
S: sample

1. A charged particle beam device comprising:
a tubular dielectric body formed with a plasma generation chamber therein;
a cylindrical outer shield disposed to surround an outer surface of the tubular dielectric body;
an inner shield disposed inside the plasma generation chamber and facing the outer shield through the dielectric body;
a coil disposed on an outer periphery of the outer shield and configured to generate a radio frequency to generate plasma in the plasma generation chamber;
an envelope surrounding the coil, the outer shield, and the dielectric body;
an aperture electrode formed with a hole for extracting ions from the plasma generation chamber; and
an extraction electrode to which a voltage for extracting ions from the plasma generation chamber is applied, wherein
a plurality of slits are formed in each of the outer shield and the inner shield.

2. The charged particle beam device according to claim 1, wherein
a potential of the outer shield is a ground potential, and a potential of the inner shield is a plasma potential.

3. The charged particle beam device according to claim 2, wherein
the inner shield is connected to the aperture electrode.

4. The charged particle beam device according to claim 2, wherein
a material of the inner shield is any one of tungsten, molybdenum, and niobium.

5. The charged particle beam device according to claim 1, wherein
the inner shield has a comb shape in which a plurality of strips are formed and one ends of the plurality of strips are connected to one another, and
the slits are each formed between the strips adjacent to each other among the plurality of strips.
